(19) United States
(12) Patent Application Publication
(10) Pub. No.: US 2003/0094677 A1
(43) Pub. Date: May 22, 2003

(54) Suspended semiconductor package

(76) Inventor: Wang Zhong Cheng, Taiping City (TW)

Correspondence Address: PRO-TECHTOR INTERNATIONAL SERVICES, 20775 Norada Court, Saratoga, CA, 95070-3018, US

(21) Appl. No.: 10/298,127

(22) Filed: Nov. 14, 2002

(30) Foreign Application Priority Data
Nov. 22, 2001 (TW) 090129225
Mar. 6, 2002 (TW) 091202741
Oct. 9, 2002 (TW) 091123539

(51) Int. Cl. H01L 23/495

(52) U.S. Cl. 257/676; 257/711

(57) ABSTRACT

Suspended semiconductor packages and methods of fabricating such semiconductor packages are disclosed. An embodiment of a suspended semiconductor package comprised of at least a bridging element having at least an upper surface and a lower surface; at least a chip having a first surface and a second surface, wherein at least a surface is the active surface, with at least a portion of the active surface conjoined to the bridging element lower surface; at least a foundational element having at least an upper surface and at least a lower surface, the foundational element being situated around the chip; and at least a conductive element electrically connecting the chip to the foundational element. Moreover, according to the present invention, wherein the bridging element may be or may not be included in the suspended semiconductor package as required, and furthermore, by mean of the usage of a bridging element, the present invention may be capable of effectively affording a number of advantages, it is possible to include a thinner semiconductor package thickness, optimal heat dissipation, excellent electrical performance and a decreased cost in production.

### BACKGROUND OF THE INVENTION

1) Field of the Invention

The invention herein relates to a semiconductor package, More particularly, it relates to a suspended semiconductor package and fabrication process.

2) Description of the Prior Art

In this present age of constantly changing high technology, research and design is underway to develop electronic products that are lightweight, thin, and compact. To achieve these objectives, all major electronics companies are involved in the intensive improvement of integrated circuits (IC) packaging technology.

Referring to FIG. 1, a conventional semiconductor package is comprised of a substrate (printed circuit board) 1, a plurality of conductive balls 2 that provide for electrical connection to another substrate, a chip 4 mounted on the top surface of the substrate 1, a plurality of conductive wires 5 electrically connecting the said chip 4 to the substrate 1, and an encapsulant resin 6 encapsulating the said substrate 1 top surface, the chip 4, and the conductive wires 5, wherein since the chip 4 is mounted on the top surface of the substrate 1 and the fabricated height of the encapsulant resin 6 must correspond to the thickness of the chip 4, the overall thickness of the said semiconductor package is thicker and, furthermore, an effective reduction for the said overall thickness is difficult, with its heat dissipation characteristics relatively poor due to the thicker encapsulant resin.

Referring to FIG. 2, another conventional semiconductor package has a lead frame 7, the said lead frame 7 having a plurality of inner leads 71 and, furthermore, a chip pad 8 at the central area of the said lead frame 7, a chip 10 mounted on the chip pad 8, a plurality of conductive wires 11 electrically connecting the said chip 4 and the said plurality of inner leads 71, and an encapsulant resin 12 encapsulating the said lead frame 7 inner leads 71, the said chip 10, and the said conductive wires 11, wherein since the fabricated height of the encapsulant resin 12 depends on the chip 10 mounted on the chip pad 8, the overall thickness of the said semiconductor package is thicker and, furthermore, an effective reduction for the said overall thickness is difficult, with its heat dissipation characteristics relatively poor due to the semiconductor package thickness and, as such, the method to reduce the thickness of the semiconductor package is to modify how the chip 10 is situated for the semiconductor package and, therefore, the industry has continuously working on improvements to achieve this objective.

Referring to the attachment, the semiconductor package disclosed in U.S. Pat. No. 5,998,857 (Semiconductor Packaging Structure with the Bar on Chip) prevents the crack of the semiconductor package due to heat exposure and consists of horizontally straddling at least one thin, long tie bar across said chip, adhering the chip to the tie bar by means of adhesive tapes, while the larger the chip size is, the longer the bar is to be used (i.e. more material is needed). In additional, Although such a structure enables the encapsulant resin to tightly encapsulate the chip to avert cracking from heat exposure, the overall thickness of the said semiconductor package is still rather thick.

In view of this, the applicant addressed the incapability of the conventional semiconductor package to effectively provide for reductions in physical size and conducted extensive research to develop the suspended semiconductor package of the invention herein and thereby solve the production technology difficulties of the prior art.

### SUMMARY OF THE INVENTION

The primary objective of the invention herein is to provide a suspended semiconductor package in which the semiconductor package effectively affords a number of advantages and capabilities, including a thinner semiconductor package, optimal heat dissipation, excellent electrical performance, and less fabrication material usage and wherein, the conductive elements respectively electrically connect a chip and a foundational element or a bridging element as required and, furthermore, traces, conductive balls, spaces, chips, and other components may be disposed on the foundational element, the bridging element, or the chip to achieve a wider scope of applications.

Therefore, the suspended semiconductor package of the invention herein is accordingly comprised of:

at least a bridging element having at least an upper surface and a lower surface;

at least a chip having a first surface and a second surface, wherein at least a surface is the active surface, with at least a portion of the said active surface conjoined to the bridging element lower surface;

at least a foundational element having at least an upper surface and at least a lower surface, the said foundational element being situated around the chip; and

at least a conductive element electrically connects the chip and the foundational element.

Moreover, according to the present invention, wherein the bridging element may be or may not be included in the suspended semiconductor package as required and, furthermore, by mean of the usage of a bridging element, the present invention may be capable of effectively affording a number of advantages, it is possible to include a thinner semiconductor package thickness, optimal heat dissipation, excellent electrical performance and a decreased cost in production.

To enable the examination committee a further understanding of the features, objectives, capabilities, and other advantages of the present invention, the brief description of the drawings are followed by the detailed description of the invention herein.

### BRIEF DESCRIPTION OF THE DRAWINGS

FIG. 1 is a cross-sectional drawing of a conventional semiconductor package (1).

FIG. 2 is a cross-sectional drawing of a conventional semiconductor package (2).

FIG. 3A is an orthographic drawing of the first embodiment of the invention herein, as viewed from the top.

FIG. 3B is a cross-sectional drawing of the first embodiment of the invention herein,

FIG. 3C is a cross-sectional drawing of the first embodiment of the invention herein that illustrates utilization at the lead frame (foundational element) structure.

FIG. 4A is an orthographic drawing of the second embodiment of the invention herein, as viewed from the top.

FIG. 4B is a cross-sectional drawing of the second embodiment of the invention herein.

FIG. 4C is a cross-sectional drawing of the second embodiment of the invention herein in the singulated apart type.

FIG. 4D is a cross-sectional drawing of the second embodiment of the invention herein that illustrates utilization at the lead frames (foundational element) structure.

FIG. 4E is a cross-sectional drawing of the lead frame (foundational element) in the singulated apart type.

FIG. 5A is an orthographic drawing of the third embodiment of the invention herein, as viewed from the top.

FIG. 5B is a cross-sectional drawing of the third embodiment of the invention herein.

FIG. 5C is a cross-sectional drawing of the third embodiment of the invention herein in the singulated apart type.

FIG. 5D is a cross-sectional drawing of the third embodiment of the invention herein that illustrates utilization at the lead frame (foundational element) structure.

FIG. 5E is a cross-sectional drawing of the lead frame (foundational element) in the singulated apart type.

FIG. 6A is an orthographic drawing of the fourth embodiment of the invention herein, as viewed from the top.

FIG. 6B is a cross-sectional drawing of the fourth embodiment of the invention herein.

FIG. 6C is an orthographic drawing of the fifth embodiment of the invention herein that illustrates utilization at the lead frame (foundational element) structure, as viewed from the top.

FIG. 6D is a cross-sectional drawing of the fifth embodiment lead frame (foundational element) of the invention herein.

FIG. 7A is an orthographic drawing of the sixth embodiment of the invention herein, as viewed from the top.

FIG. 7B is a cross-sectional drawing of the sixth embodiment of the invention herein.

FIG. 8 is a cross-sectional drawing of the seventh embodiment of the invention herein.

FIG. 9A is an orthographic drawing of the eighth embodiment of the invention herein, as viewed from the top.

FIG. 9B is a cross-sectional drawing of the eighth embodiment of the invention herein.

FIG. 10A is an orthographic drawing of the ninth embodiment of the invention herein, as viewed from the top.

FIG. 10B is a cross-sectional drawing of the ninth embodiment of the invention herein.

FIG. 10C is a cross-sectional drawing of another structural iteration of the ninth embodiment of the invention herein.

FIG. 11 is a cross-sectional drawing of the tenth embodiment of the invention herein.

FIG. 12A is a cross-sectional drawing of the eleventh embodiment of the invention herein.

FIG. 12B is a cross-sectional drawing of the eleventh embodiment of the invention herein that illustrates utilization at the lead frame (foundational element) structure.

FIG. 13A is a cross-sectional drawing of the twelfth embodiment of the invention herein.

FIG. 13B is a cross-sectional drawing of the twelfth embodiment of the invention herein that illustrates utilization at the lead frame (foundational element) structure.

FIG. 14 is a cross-sectional drawing of the thirteenth embodiment of the invention herein.

FIG. 15A is a cross-sectional drawing of the fourteenth embodiment of the invention herein.

FIG. 15B is a cross-sectional drawing of the fourteenth embodiment of the invention herein that illustrates utilization at the lead frame (foundational element) structure.

FIG. 15C is a cross-sectional drawing of the fourteenth embodiment of the invention herein that shows the chips stacked.

FIG. 15D is a cross-sectional drawing of the fourteenth embodiment of the invention herein that illustrates utilization at the lead frame (foundational element) structure of the chips stacked.

FIG. 16A is a cross-sectional drawing of the fifteenth embodiment of the invention herein (1).

FIG. 16B is a cross-sectional drawing of the fifteenth embodiment of the invention herein (2).

FIG. 17A is a cross-sectional drawing of the sixteenth embodiment of the invention herein (1).

FIG. 17B is a cross-sectional drawing of the sixteenth embodiment of the invention herein (2).

FIG. 17C is a cross-sectional drawing of the sixteenth embodiment of the invention herein (3).

FIG. 17D is a cross-sectional drawing of the sixteenth embodiment of the invention herein (4).

FIG. 18A is an orthographic drawing of the seventeenth embodiment of the invention herein, as viewed from the top.

FIG. 18B is a cross-sectional drawing of the seventeenth embodiment of the invention herein.

FIG. 18C is a cross-sectional drawing of the seventeenth embodiment of the invention herein that illustrates utilization at the lead frame (foundational element) structure.

FIG. 19A is an orthographic drawing of the eighteenth embodiment of the invention herein, as viewed from the top.

FIG. 19B is a cross-sectional drawing of the eighteenth embodiment of the invention herein.

FIG. 19C is a cross-sectional drawing of the eighteenth embodiment of the invention herein that illustrates utilization at the lead frame (foundational element) structure.

FIG. 20A is an orthographic drawing of the nineteenth embodiment of the invention herein, as viewed from the top.

FIG. 20B is a cross-sectional drawing of the nineteenth embodiment of the invention herein.

FIG. 20C is a cross-sectional drawing of the nineteenth embodiment of the invention herein that illustrates utilization at the lead frame (foundational element) structure.

FIG. 21A is an orthographic drawing of the twentieth embodiment of the invention herein, as viewed from the top.

FIG. 21B is a cross-sectional drawing of the twentieth embodiment of the invention herein.

FIG. 21C is a cross-sectional drawing of the twentieth embodiment of the invention herein that illustrates utilization at the lead frame (foundational element) structure.

FIG. 22A is an orthographic drawing of the twenty-first embodiment of the invention herein, as viewed from the top.

FIG. 22B is a cross-sectional drawing of the twenty-first embodiment of the invention herein.

FIG. 22C is a cross-sectional drawing of the twenty-first embodiment of the invention herein that illustrates utilization at the lead frame (foundational element) structure.

FIG. 23A is an orthographic drawing of the twenty-second embodiment of the invention herein, as viewed from the top.

FIG. 23B is a cross-sectional drawing of the twenty-second embodiment of the invention herein.

FIG. 23C is a cross-sectional drawing of the twenty-second embodiment of the invention herein that illustrates utilization at the lead frame (foundational element) structure.

FIG. 24A is an orthographic drawing of the twenty-third embodiment of the invention herein, as viewed from the top.

FIG. 24B is a cross-sectional drawing of the twenty-third embodiment of the invention herein.

FIG. 25A is an orthographic drawing of the twenty-fourth embodiment of the invention herein, as viewed from the top.

FIG. 25B is a cross-sectional drawing of the twenty-fourth embodiment of the invention herein.

FIG. 25C is a cross-sectional drawing of another structural iteration of the twenty-fourth embodiment of the invention herein.

FIG. 25D is a cross-sectional drawing of yet another structural iteration of the twenty-fourth embodiment of the invention herein.

FIG. 26A is a cross-sectional drawing of the twenty-fifth embodiment of the invention herein (1).

FIG. 26B is a cross-sectional drawing of the twenty-fifth embodiment of the invention herein (2).

FIG. 26C is a cross-sectional drawing of the twenty-fifth embodiment of the invention herein (3).

FIG. 27A is an orthographic drawing of the twenty-sixth embodiment of the invention herein, as viewed from the top.

FIG. 27B is a cross-sectional drawing of the twenty-sixth embodiment of the invention herein.

FIG. 28A is a cross-sectional drawing of the twenty-seventh embodiment fabrication process of the invention herein (1).

FIG. 28B is a cross-sectional drawing of the twenty-seventh embodiment fabrication process of the invention herein (2).

FIG. 28C is a cross-sectional drawing of the twenty-seventh embodiment fabrication process of the invention herein (3).

FIG. 28D is a cross-sectional drawing of the twenty-seventh embodiment fabrication process of the invention herein (4).

FIG. 29A is a cross-sectional drawing of the twenty-eighth embodiment fabrication process of the invention herein (1).

FIG. 29B is a cross-sectional drawing of the twenty-eighth embodiment fabrication process of the invention herein (2).

FIG. 29C is a cross-sectional drawing of the twenty-eighth embodiment fabrication process of the invention herein (3).

FIG. 30A is an orthographic drawing of the twenty-ninth embodiment fabrication process of the invention herein (1).

FIG. 30B is a cross-sectional drawing of the twenty-ninth embodiment fabrication process of the invention herein (2).

FIG. 30C is a cross-sectional drawing of the twenty-ninth embodiment fabrication process of the invention herein (3).

FIG. 30D is a cross-sectional drawing of the twenty-ninth embodiment fabrication process of the invention herein (4).

FIG. 30E is a cross-sectional drawing of the twenty-ninth embodiment fabrication process of the invention herein (5).

FIG. 31A is an orthographic drawing of the thirtieth embodiment fabrication process of the invention herein (1).

FIG. 31B is a cross-sectional drawing of the thirtieth embodiment fabrication process of the invention herein (2).

FIG. 31C is a cross-sectional drawing of the thirtieth embodiment fabrication process of the invention herein (3).

FIG. 31D is a cross-sectional drawing of the thirtieth embodiment fabrication process of the invention herein (4).

FIG. 32 is a diagram of the fabrication process utilized by the invention herein.

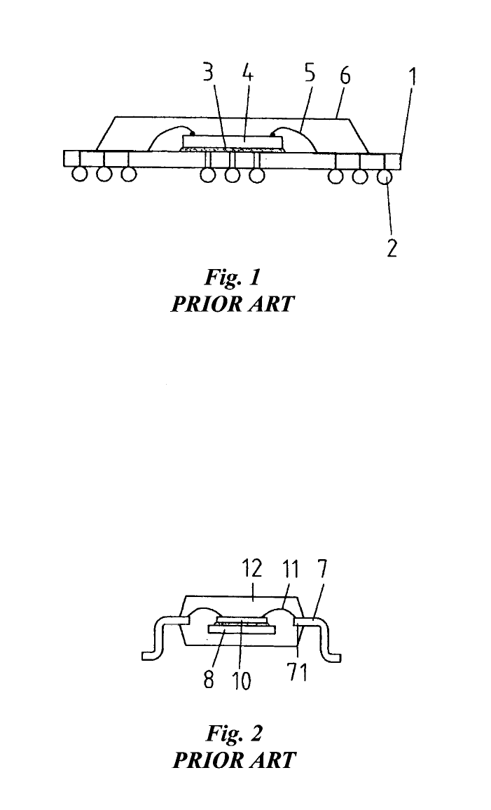

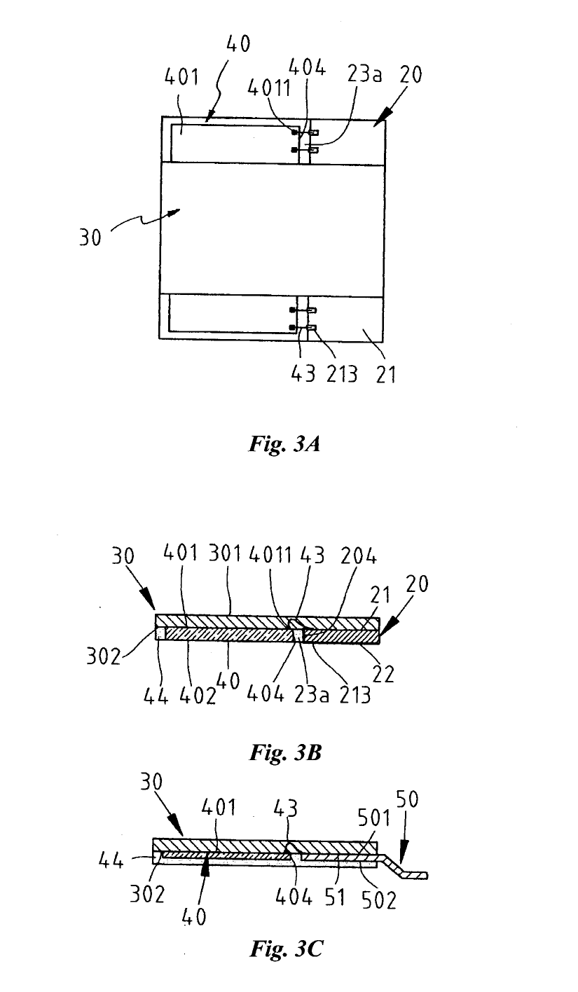

Attachment 1, U.S. Pat. No. 5,998,857.

### DETAILED DESCRIPTION OF THE INVENTION

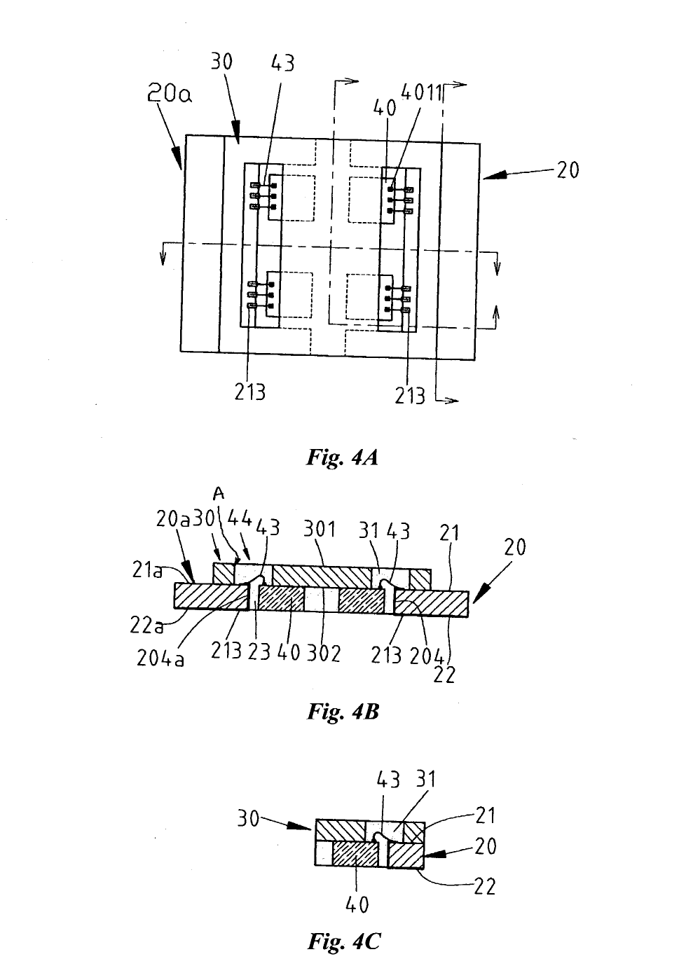

To introduce the first preferred embodiment of the suspended semiconductor package of the present invention, refer to FIG. 3A, FIG. 3B, and FIG. 3C, wherein as indicated in FIGS. 3A and 3B, the drawings of the suspended semiconductor package of the invention herein with a substrate serving as the foundational element, the said embodiment is comprised of:

A bridging element 30 having an upper surface 301 and a corresponding lower surface 302; a chip 40 having a first surface 401 and a corresponding second surface 402, wherein the first surface 401 is the active surface; a plurality of bond pads 4011 disposed any place of the chip 40 first surface 401 that provide for external electrical connectivity; wherein the bond pads 4011 disposed on the periphery of the chip 40 first surface 401 in the embodiment herein; a space 23a formed between the bridging element 30 lower surface 302 and the periphery at one side of the chip 40 due to the conjoinment of the chip 40 first surface 401 to a portion of the bridging element 30 lower surface 302; a foundational element 20 having an upper surface 21 and a corresponding lower surface 22, the said upper surface 21 conjoined to a portion of the bridging element 30 lower surface 302 positioned at the said space 23a; a plurality of traces 213 situated on the foundational element 20 upper surface 21 and, furthermore, the said traces 213 extending from the upper surface21 along the peripheral edge 204 of the foundational element 20 to the lower surface 22 to provide for electrical connection; a plurality of conductive elements 43 (conductive wires in the embodiment herein) electrically connecting the chip 40 bond pads 4011 and the traces 213; and an encapsulant resin 44 encapsulating the said bridging element 30, the said foundational element 20, the said chip 40, and the said plurality of conductive elements 43; in the said embodiment, the chip 40 and the foundational element 20 are respectively conjoined to the bridging element 30 such that the foundational element 20 is positioned around or adjacent to a side of the periphery of the chip 40, thereby effectively reducing the thickness of the suspended semiconductor package and, furthermore, optimizing its heat dissipation performance (the heat dissipation path is shorter), optimizing its electrical performance (the electrical paths are shorter), and decreasing the amount of material utilized (the semiconductor package thickness is thinner).

As indicated in FIG. 3C, the drawings of the suspended semiconductor package of the invention herein with a lead frame serving as the foundational element, the said embodiment is comprised of:

A foundational element 50 having a plurality of upper surfaces 501, a plurality of lower surfaces 502, and a plurality of inner leads 51; a bridging element 30; a chip 40 conjoined to the lower surface 302 of the bridging element 30, with the upper surfaces 501 of inner leads 51 of the foundational element 50 also coupled with the bridging element 30 lower surface 302 such that the foundational element 50 inner leads 51 are positioned around a side along the periphery of the chip 40; conductive elements 43 electrically connected the said chip 40 to inner leads 51; and an encapsulant resin 44 encapsulating the said bridging element 30, the said inner leads 51, the said chip 40, and the said conductive elements 43; as such, the chip 40 coupled with the bridging element 30 lower surface 302 enables the positioning of the inner leads 51 around or adjacent to a side along the periphery of the chip 40 such that the thickness of the suspended semiconductor package of the invention herein is thinner, requires less material, and shares the same said advantages.

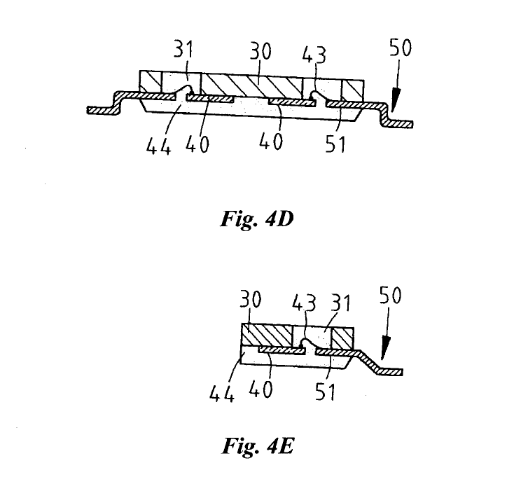

Furthermore, as indicated in FIG. 4A, FIG. 4B, FIG. 4C, FIG. 4D, and FIG. 4E, the second embodiment of the invention herein, wherein FIG. 4A, FIG. 4B, and FIG. 4C are drawings of the suspended semiconductor package of the invention herein with substrates serving as the foundational elements, while FIG. 4D and FIG. 4E are drawings of the suspended semiconductor package of the invention herein with lead frames serving as the foundational elements in which since some of the structural features are identical to those of the preceding embodiments, the same numerals are extended to the present embodiment and, referring to FIG. 4A and FIG. 4B, the embodiment of the present invention is comprised of:

A bridging element 30 having an upper surface 301 and a corresponding lower surface 302; a plurality of penetrable spaces 31 cavitated in the said bridging element; two foundational elements 20 and 20a each having a respective upper surface 21 and 21a as well as a respective lower surface 22 and 22a; a penetrable containment space 23 formed by the corresponding paired arrangement of the said two foundational elements 20 and 20a and, furthermore, the upper surfaces 21 and 21a of the said two foundational elements 20 and 20a are each conjoined to the said bridging element 30 lower surface 302 such that the said containment space 23 is contiguous with the bridging element 30 spaces 31; a plurality of traces 213 situated on the foundational elements 20 and 20a upper surfaces 21 and 21a and, furthermore, the said traces 213 extend from the interior peripheral edges 204 and 204a along the sides of the foundational elements 20 and 20a to the lower surfaces 22 and 22a to provide for electrical connectivity; a plurality of chips 40 conjoined to or coupled with the bridging element 30 lower surface 302 and positioned inside the space 23; a plurality of conductive elements 43 electrically connecting the said chips 40 to traces 213 and, furthermore, the conductive elements 43 are in the spaces 31; and an encapsulant resin 44 encapsulating the spaces 31 and the containment space 23, the said embodiment similarly possessing the said advantages of a reduction for the semiconductor package thickness.

As indicated in FIG. 4C, the drawing of the embodiment after the singulating process illustrating that the said embodiment may be sliced apart horizontally or vertically, with the different directions and number of repetitions possible enabling the present invention of suspended semiconductor package in various arrangements that similarly achieve the objectives of thinner semiconductor package thickness and less material usage.

As indicated in FIG. 4D, the said embodiment of the present invention is comprised of:

A foundational element 50 having inner leads 51; a bridging element 30 having a plurality of spaces 31 disposed on the bridging element 30, wherein the inner leads 51 is attached to the bridging element 30; a plurality of chips 40 conjoined to the bridging element 30 lower surface such that the said inner leads 51 are positioned around the sides along the peripheries of the chips 40; a plurality of conductive elements 43 electrically connect the chips 40 and the inner leads 51; and an encapsulant resin 44 that encapsulates the said inner leads 51, the said chips 40, and the said conductive elements 43, thereby similarly achieving the objectives of thinner semiconductor package thickness and the less material usage.

As indicated in FIG. 4E, the drawing of the singulated apart embodiment in FIG. 4D, the objectives of thinner semiconductor package thickness and the less material usage are similarly achieved.

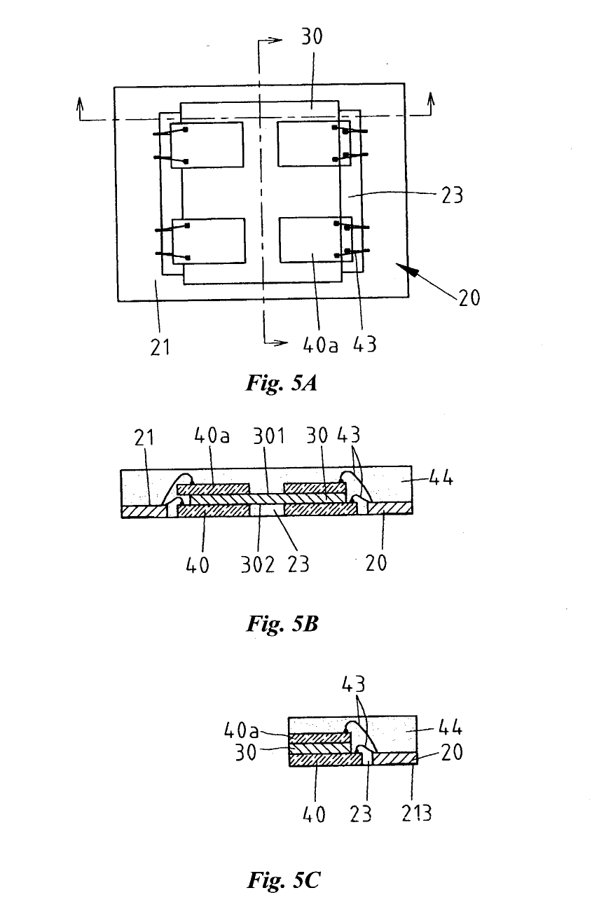

Moreover, as indicated in FIG. 5A, FIG. 5B, FIG. 5C, FIG. 5D, and FIG. 5E, the third embodiment of the invention herein, of which FIG. 5A, FIG. 5B, and FIG. 5C are drawings of the suspended semiconductor package of the invention herein with a substrate serving as the foundational element, while FIG. 5D and FIG. 5E are drawings of the suspended semiconductor package of the invention herein with a lead frame serving as the foundational element, wherein since some of the structural features are identical to those of the preceding embodiments, the same numerals are extended to the present embodiment and, referring to FIG. 5A and FIG. 5B, the embodiment is comprised of a foundational element 20 cavitated with a penetrable containment space 23; a bridging element 30 conjoined to the foundational element 20 upper surface 21, the said bridging element 30 upper surface 301 and lower surface 302 respectively conjoined to a plurality of chips 40 and 40a and, furthermore, the said chips 40 are positioned inside the foundational element 20 containment space 23, the active surfaces of the chips 40 and 40a respectively electrically connected to the foundational element 20 via conductive elements 43; and sealed by an encapsulant resin 44; the said structure may also be singulated apart to similarly have the advantages of the said reduction for the semiconductor package thickness, wherein after the bridging element 30 in FIG. 5B is sliced apart, the bridging element 30 does not contact the foundational elements 20, wherein the foundational elements 20 are still positioned around the peripheries of the chips 40.

As indicated in FIG. 5C, the drawing of the singulated apart embodiment showing that singulation may be done according to requirements to fabricate structures of differing shape as well as similarly achieving the objectives of thinner semiconductor package thickness and less material usage, wherein after the bridging element 30 is sliced apart, the bridging element 30 does not contact the foundational element 20.

As previously stated (regarding FIG. 5A, FIG. 5B, and FIG. 5C), lead frames may be utilized as the foundational element on the structure herein, as indicated in FIG. 5D and FIG. 5E, to similarly achieve thinner semiconductor package thickness and the less material usage, wherein after the bridging element 30 in FIG. 5D and FIG. 5E is singulated apart, the bridging element 30 does not contact the foundational elements 50 and the foundational elements 50 are positioned around the peripheries of the chips 40.

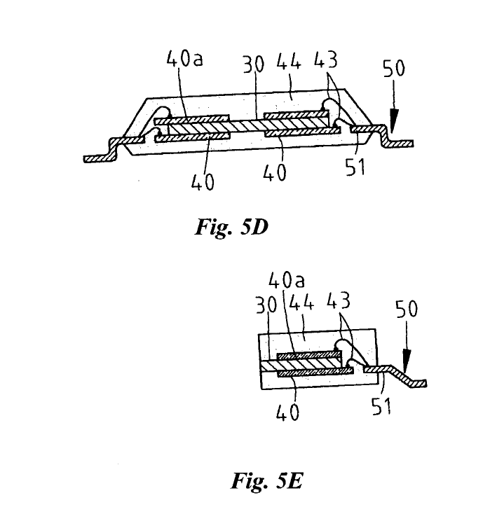

As indicated in FIGS. 6A and 6B, the fourth embodiment of the invention herein; since some of the structural features are identical to those of the preceding embodiments, the same numerals are extended to the present embodiment and, referring to FIG. 6A and FIG. 6B, in this embodiment since a first foundational element (substrate) 20 and a second foundational element (lead frame) 50 are involved in the embodiment of the present invention, more variations in foundational element material composition are possible to effectively achieve wider applications.

As indicated in FIGS. 6C and 6D, the fifth embodiment of the invention herein, a suspended semiconductor package of the invention herein with a lead frame serving as the foundational element; since some of the structural features are identical to those of the preceding embodiments, the same numerals are extended to the present embodiment, wherein the chip 40 is conjoined onto two bridging elements 30, the said bridging elements 30 then conjoined to a foundational element 50 having a plurality of inner leads 51, enabling the foundational element 50 to be positioned around the peripheries of the chip 40 (in the embodiment herein, the foundational element 50 is circularly situated around the chip 40) and, furthermore, the foundational element 50 inner leads 51 may, as per requirements, extend outward from the encapsulant resin 44 and be contoured into differing curvatures or shapes.

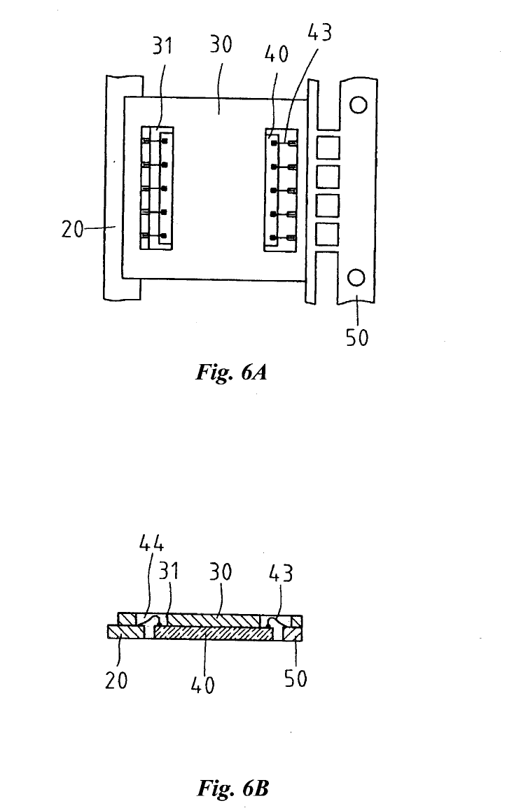

As indicated in FIGS. 7A and 7B, the drawings of the sixth embodiment of the invention herein which illustrate that since the foundational element and the bridging element are merged into a single unitary entity having foundational element functionality in a bridging element structural arrangement, the said bridging element 30 has a plurality of upper surfaces 301 and 301a as well as a plurality of lower surfaces 302 and 302a cavitated with a penetrable space 31; the chip 40 is first placed inside the bridging element 30 space 31 and placed in electrical connection with the bridging element 30 second upper surface 301a via conductive elements (wires) 43, a chip 41 is then placed in electrical connection with the lower (second) surface 302a via conductive elements (bumps) 43, and the encapsulant resin 44 is filled into the bridging element 30; in the said structure, matching the foundational element is not required and thus thickness is thinner, material is saved, and the fabrication process is simplified.

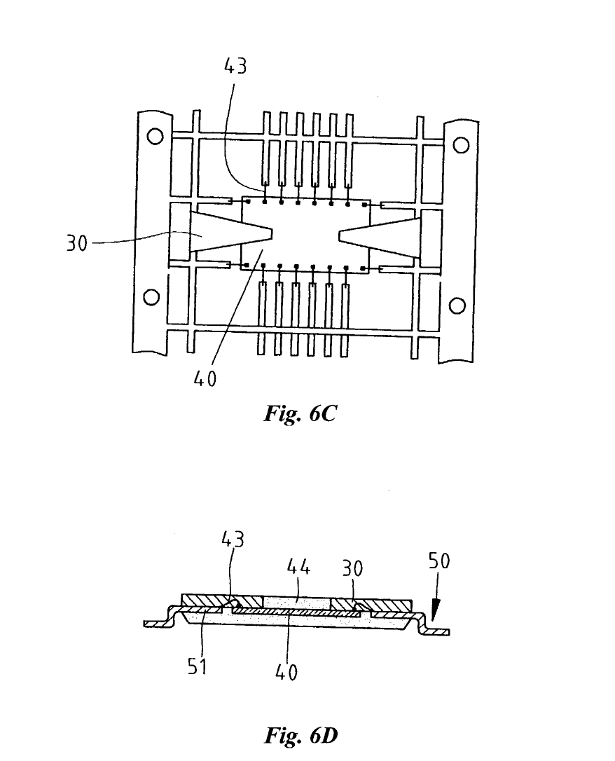

As indicated in FIG. 8, the drawing of the seventh embodiment of the invention herein which illustrates that two foundational elements 20 and 20a are utilized in the structure of the said embodiment, wherein the foundational element 20a upper surface 21a is conjoined to a bridging element 30 lower surface 302, while the foundational element 20 does not contact the bridging element 30, the two foundational elements 20 and 20a are both positioned around the peripheries of a plurality of chips 40, and the encapsulant resin 44 encapsulates the said bridging element 30, the two foundational elements 20 and 20a, the chips 40, and the said conductive elements 43.

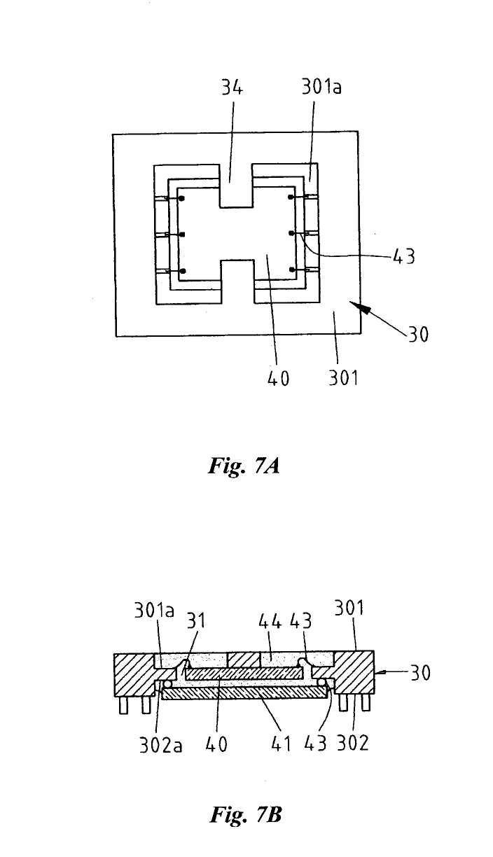

As indicated in FIG. 9A and FIG. 9B, the drawings of the eighth embodiment of the invention herein which illustrate that the bridging element 30 and the outer frame consists of a single unitary entity (the bridging element 30 and the outer frame may also be disposed separately) in the embodiment herein, the bridging element 30 and the foundational element 20 both have conduction pads 61 disposed on their upper and lower surfaces, wherein conductive through-holes (via) 62 are also formed in both the bridging element 30 and the foundational element 20 to provide for electrical connectivity between the upper and lower conduction pads 61 of the bridging element 30 and the foundational element 20 and, furthermore, the traces 38 of the embodiment herein proceed from the bridging element 30 lower surface 302 through their exterior peripheral edges 306 (or interior peripheral edges 307) to the bridging element 30 upper surface 301.

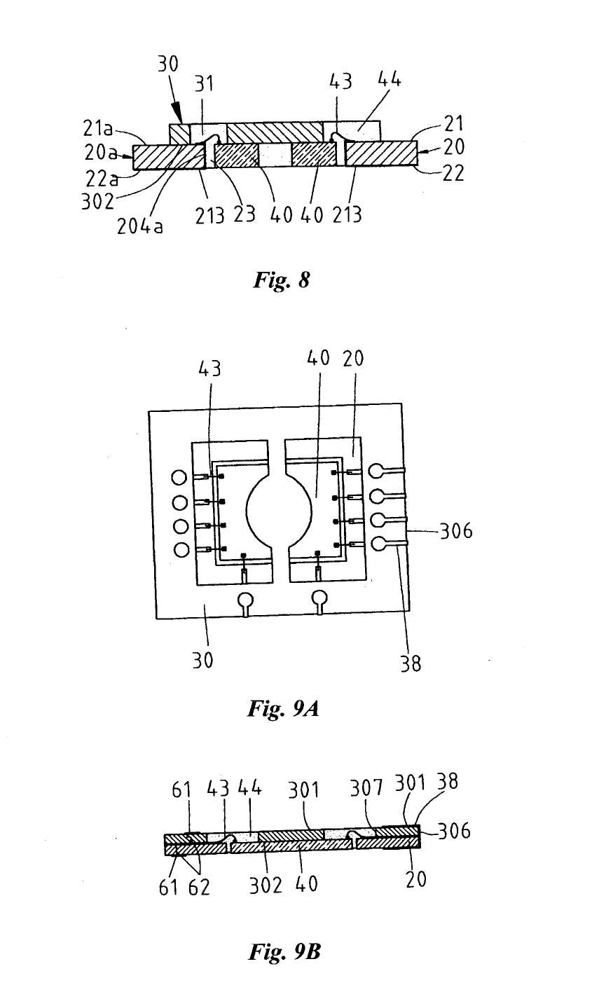

As indicated in FIG. 10A and FIG. 10B, the drawings of the ninth embodiment of the invention herein which illustrate that the active surface of the chip 40 and the foundational element 20 are conjoined to the bridging element 30 lower surface, wherein the foundational element 20 has a space 23 enabling the placement of the chip 40 inside the space 23, a plurality of traces 213 are disposed on the foundational element 20 upper surface 21, the said traces 213 extending from the foundational element 20 upper surface 21 and along an interior peripheral edge 204 (or exterior peripheral edge 205) to the lower surface 22 to achieve electrical connection with conductive balls 33; additionally, in the embodiment herein, an conductive ring (not shown in the drawings) may be circularly situated around the space 23 of the foundational element 20 upper surface 21, with a portion of the said conductive ring (not shown in the drawings) coupled with the bridging element 30 lower surface 302 or the said conductive ring (not shown in the drawings) may be circularly situated around the chip 40, coupled with the bridging element 30 lower surface 302, and suspended in the foundational element 20 space 23; the said conductive ring (not shown in the drawings) may be disposed in differing shapes and quantities as required and, furthermore, serves as a junctioning means of positive power, negative power, signal transfers, grounding, and electromagnetic interference prevention, furthermore the conductive ring (not shown in the drawings) may be coupled with other components; and as indicated in FIG. 10C, the foundational element 20 and the chip 40 are conjoined to the bridging element 30, with the bridging element 30 nested in the foundational element 20 space 23.

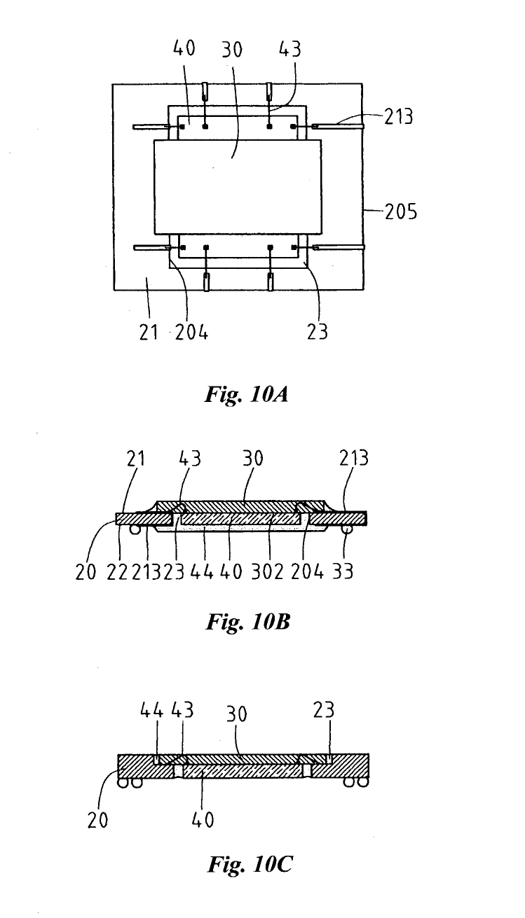

As indicated in FIG. 11, the drawing of the tenth embodiment of the invention herein which illustrates a protruding section 32 disposed on the bridging element lower surface (the said protruding section 32 is a separate part and is assembled to the bridging element 30); in the embodiment herein, the protruding section 32 and the bridging element 30 are combined as a single unitary entity, wherein the active surface of the chip 40 is coupled with the protruding section 32 and, furthermore, the foundational element 20 is conjoined to the bridging element 30 and situated around the chip 40; furthermore, the protruding section 32 may be disposed in differing quantities and shapes as required to thereby adjust chip 40 position.

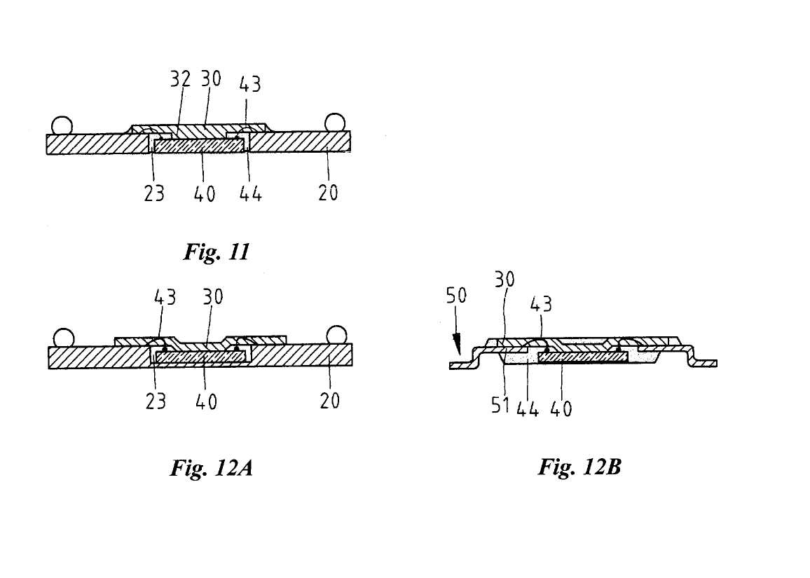

As indicated in FIG. 12A and FIG. 12B, the drawings of the eleventh embodiment of the invention herein, FIG. 12A shows that the foundational element 20 has an impenetrable space 23, but enables the nesting of the chip 40 and, furthermore, the bridging element 30 has a plurality of upper and lower surfaces, the foundational element 20 is conjoined to the bridging element 30, the active surface of the chip 40 is coupled with the bridging element 30, and the embodiment shown in FIG. 12B and FIG. 12A is of an identical structural arrangement; however, in the structural arrangement of FIG. 12B, the foundational element 50 is a lead frame.

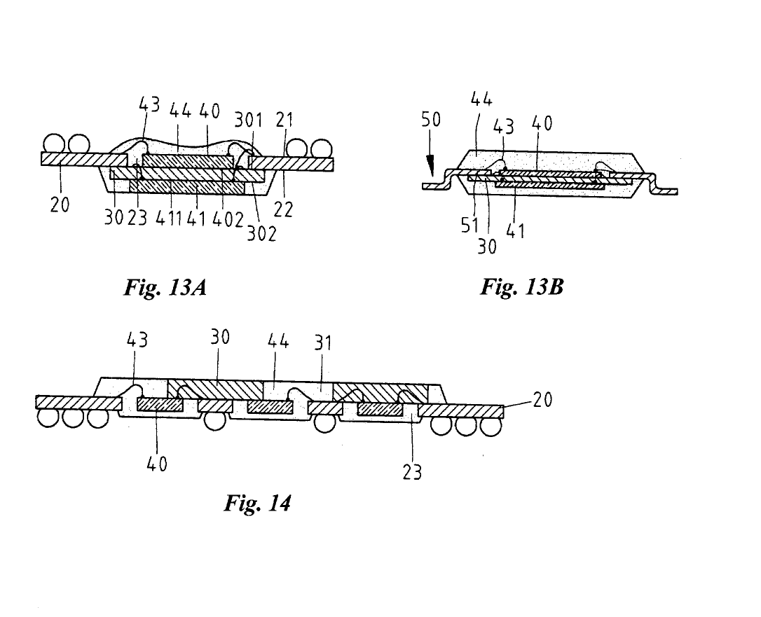

As indicated in FIGS. 13A and 13B, the drawings of the twelfth embodiment of the invention herein which illustrate the foundational element 20 having a penetrable space 23 such that after the bridging element 30 is conjoined to the foundational element 20 lower surface 22, the second surface (the inactive surface) 402 of a first chip 40 is coupled with the bridging element 30 upper surface 301 and the first surface (active surface) 411 of a second chip41 is coupled with the bridging element 30 lower surface 302, thereby enabling multiple chips stacked, and the embodiment shown in FIG. 13B and FIG. 13A is of an identical structural arrangement; however, in the structural arrangement of FIG. 13B, the foundational element 50 is a lead frame.

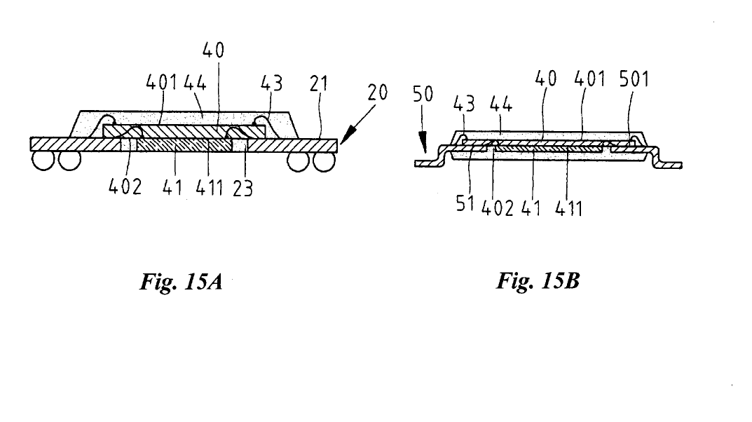

As indicated in FIG. 14, the drawing of the thirteenth embodiment of the invention herein which illustrates that the foundational element 20 and a plurality of chips 40 are conjoined to a plurality of bridging elements 30 to form a module, wherein the chips 40 active surfaces are coupled with the plurality of bridging elements 30 to enable a multi-chip module.

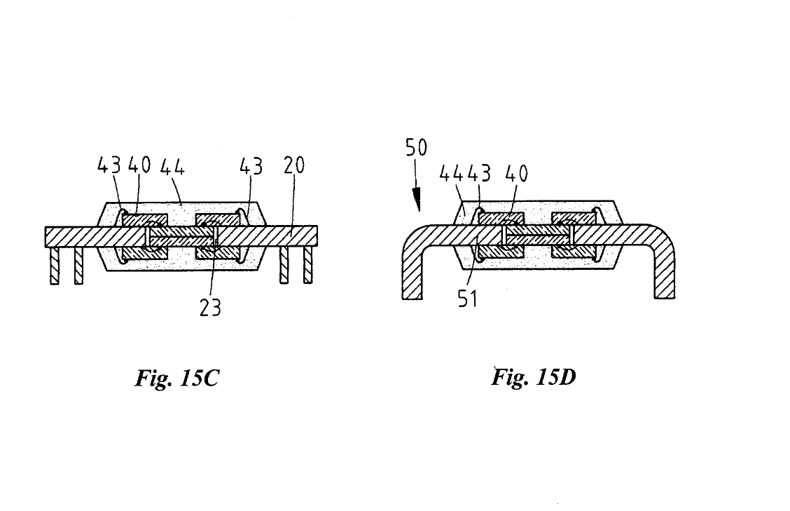

As indicated in FIG. 15A, FIG. 15B, FIG. 15C, and FIG. 15D, the drawings of the fourteenth embodiment of the invention herein, refer to FIG. 15A and FIG. 15B, which illustrate that the bridging element consists of a first chip 40(i.e. the first chip 40 is served as a bridging element), with the first surface (active surface) 411 of a second chip 41 and the upper surface 21 of the foundational element 20 conjoined to the first chip 40 second surface 402 (the said second surface 402 may be disposed as either the inactive surface or the active surface as required); in the said embodiment, the first surface 401 of the first chip 40 is the active surface only and the conductive elements 43 enables electrical connection to the foundational element 20, moreover with the bridging elements shown in FIG. 15C and FIG. 15D consisting of a plurality of chips 40.

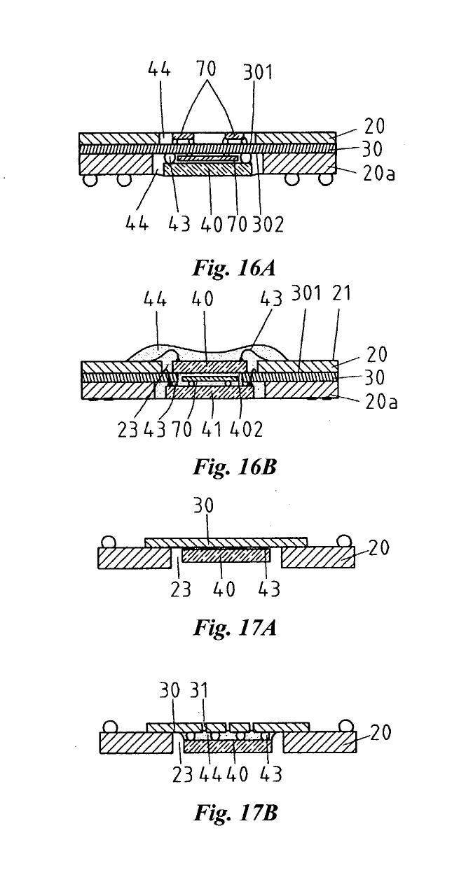

As indicated in FIG. 16A and FIG. 16B, the drawings of the fifteenth embodiment of the invention herein in which the bridging element 30 and two foundational elements 20 and 20a are formed together; in the said embodiment, the two foundational elements 20 and 20a as well as the chips 40 and 41 are each conjoined to the bridging element 30, wherein as shown in FIG. 16A, the chip 40 is a flip chip and the conductive elements (bumps) 43 electrically connecting the bridging element 30 lower surface 302 to the chip 40 and, as indicated in FIG. 16B, the second surface (the inactive surface) 402 of the chip 40 is conjoined to the bridging element 30 upper surface 301 and situated inside the space 23, the conductive elements 43 electrically connecting to the foundational element 20 upper surface 21 (or the bridging element 30 upper surface 301) and, furthermore, as shown in FIG. 16A and FIG. 16B, another components 70 are disposed on the upper surface 301 and the lower surface 302 of the bridging element 30 as well as the chip 41.

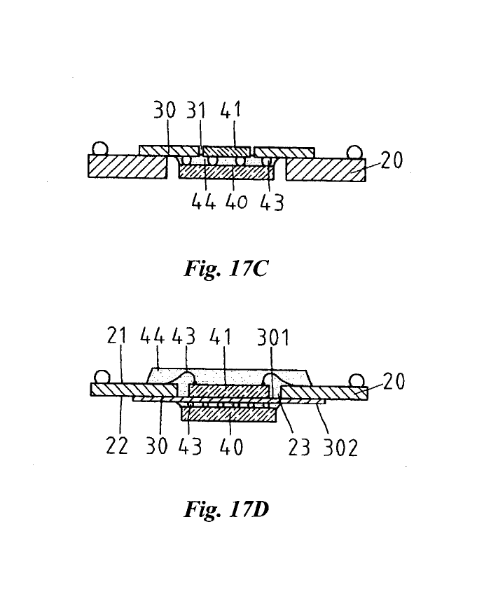

As indicated in FIG. 17A, FIG. 17B, FIG. 17C, and FIG. 17D, the drawings of the sixteenth embodiment of the invention herein which illustrate that the conductive elements 43 on the chip 40 are electrically connected to the bridging element 30 and, as shown in FIG. 17B, the bridging element 30 has a plurality of spaces 31, enabling the encapsulant resin 44 to be filled into the said spaces 31; as indicated in FIG. 17C, the active surface of the chip 41 is electrically connected to the chip 40, with the chip 41 nested inside the bridging element 30 spaces 31; and, as shown in FIG. 17D, the bridging element 30 is conjoined to the foundational element 20 lower surface 22 and the active surface of the chip 40 is conjoined to the bridging element 30 lower surface 302, with the chip 41 nested in the foundational element 20 space 23 and coupled with the bridging element 30 upper surface 301.

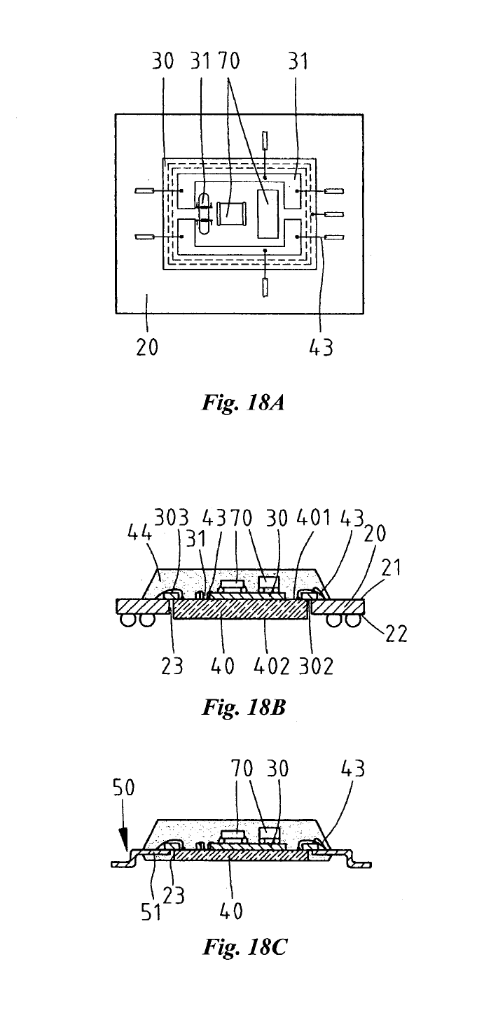

As indicated in FIG. 18A, FIG. 18B, and FIG. 18C, the drawings of the seventeenth embodiment of the invention herein which illustrate that the first surface (active surface) 401 of the chip 40 and the foundational element 20 upper surface 21 are conjoined to the bridging element 30 lower surface 302, then the foundational element 20 space 23 is impenetrable, the conductive elements 43 go through the bridging element 30 space 31 and electrically connect the chip 40 to the bridging element 30 and, furthermore, some of the conductive elements 43 also pass over the portion 303 of the bridging element 30 and electrically connect the chip 40 to the foundational element 20, such that, the portion 303 of bridging element 30 may prevent the conductive elements 43 from sag (collapse) problems, furthermore, the chip 40 lower surface 402 projects from the encapsulant resin 44 or the planar level of the foundational element 20 lower surface 22, and the embodiment shown in FIG. 18C and FIG. 18B is of an identical structural arrangement; however, in the structural arrangement of FIG. 18C, the foundational element 50 is a lead frame.

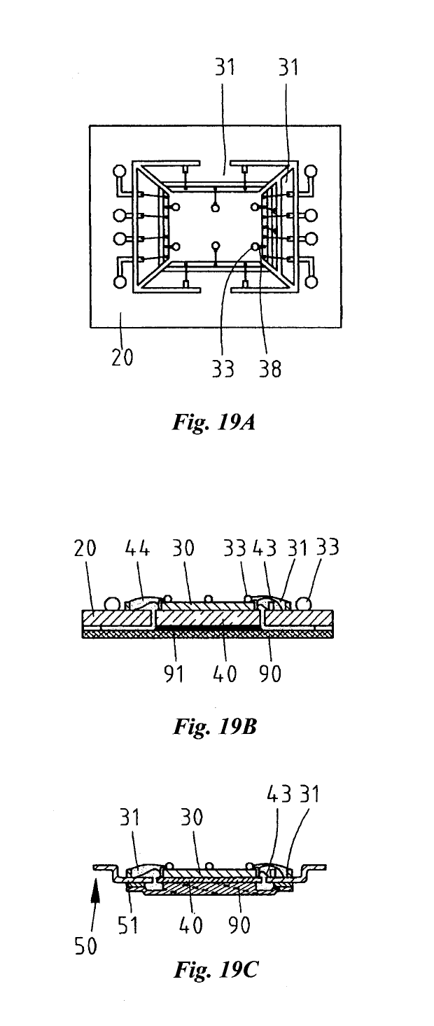

As indicated in FIG. 19A, FIG. 19B, and FIG. 19C, the drawings of the eighteenth embodiment of the invention herein which illustrate that the bridging element 30 has traces 38, a plurality of conductive balls 33 disposed on the traces 38 and a plurality of spaces 31, wherein some of the said spaces 31 are unsealed; in the said embodiment, the conductive elements 43 are respectively electrically connected to the chip 40, traces 38 of the bridging element 30, and the foundational element 20 furthermore after the chip 40 is conjoined to the bridging element 30, a heat sink 90 placed (attached) on the second surface of the said chip 40 to facilitate chip 40 heat dissipation, and the embodiment shown in FIG. 19C and FIG. 19B is of an identical structural arrangement; however, in the structural arrangement of FIG. 19C, the foundational element 50 is a lead frame.

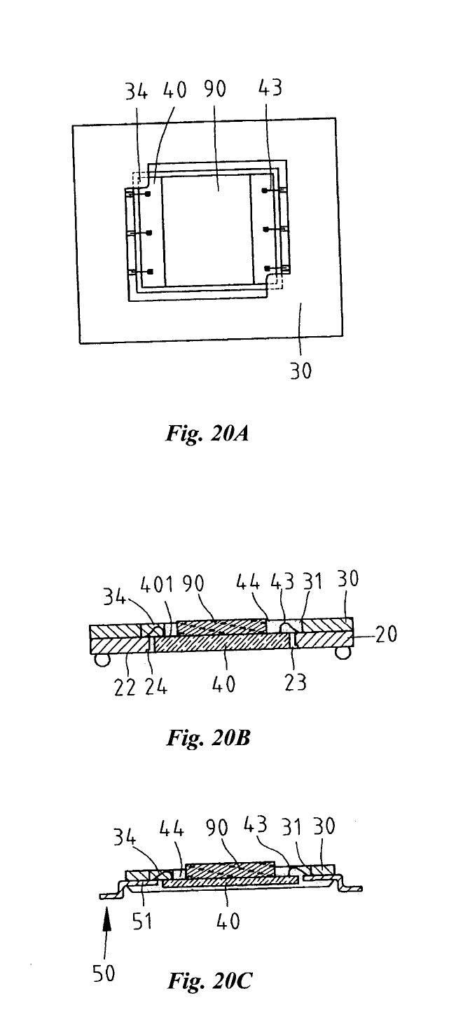

As indicated in FIG. 20A, FIG. 20B, and FIG. 20C, the drawings of the nineteenth embodiment of the invention herein which illustrate that the chip 40 is coupled with a protruding portion 34 of the bridging element 30, the foundational element 20 is conjoined to the bridging element 30 lower surface, the heat sink 90 is placed on the active surface 401 of the chip 40, furthermore, the foundational element 20 space 23 along the peripheral edge, such that there are a plurality of lower surfaces 22, with at least a recessed portion 24 formed, and the embodiment shown in FIG. 20C and FIG. 20B is of an identical structural arrangement; however, in the structural arrangement of FIG. 20C, the foundational element 50 is a lead frame.

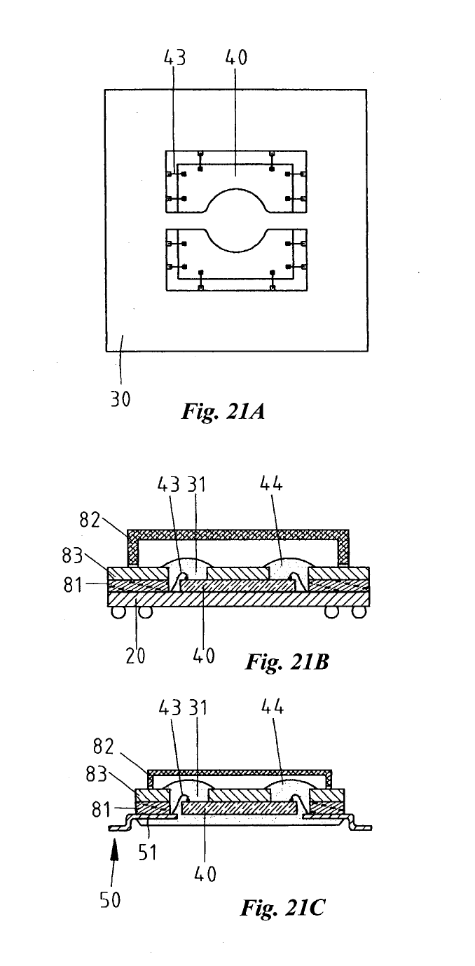

As indicated in FIG. 21A, FIG. 21B, and FIG. 21C, the drawings of the twentieth embodiment of the invention herein which illustrate that the bridging element 30 consists of two submembers 81 and 83 integrated together (the submember 81 may also be viewed as a part of the foundational element 20), the chip 40 is conjoined to the bridging element 30 and also nested in a space 31 therein and, furthermore, the foundational element 20 is conjoined to the bridging element 30, wherein the thickness of the submember 81 may be adjusted as required; in the said embodiment, since a lid 82 overlays the conductive elements 43, the encapsulant resin 44 may be incorporated or dispensed with as required. Furthermore, the embodiment shown in FIG. 21C and FIG. 21B is of an identical structural arrangement; however, in the structural arrangement of FIG. 21C, the foundational element 50 is a lead frame.

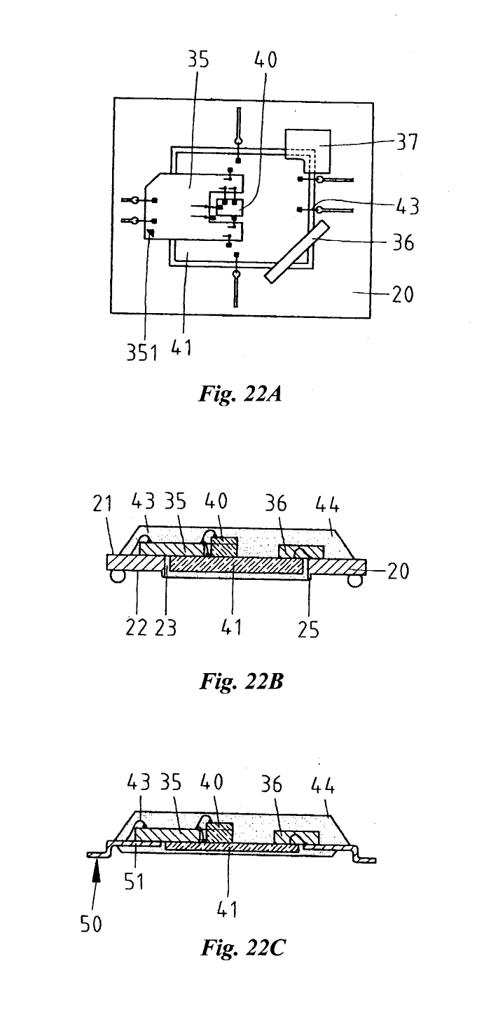

As indicated in FIG. 22A, FIG. 22B, and FIG. 22C, the drawings of the twenty-first embodiment of the invention herein which illustrate that a plurality of differently shaped bridging elements 35, 36, and 37 are disposed on the foundational element 20, the chip 40 is positioned in the unsealed space of a U-shaped bridging element 35 and conjoined to another chip 41, and the chips 40 and 41, the foundational element 20, and the bridging element 35 are each in electrical connection with the conductive elements 43, wherein the bridging element 35 has a marking 351 that provides for alignment and the foundational element 20 has a space 23 disposed along the peripheral edge of its lower surface, a plurality of lower surfaces 22, with at least a protruding portion 25 formed. Furthermore, the embodiment shown in FIG. 22C and FIG. 22B is of an identical structural arrangement; however, in the structural arrangement of FIG. 22C, the foundational element 50 is a lead frame.

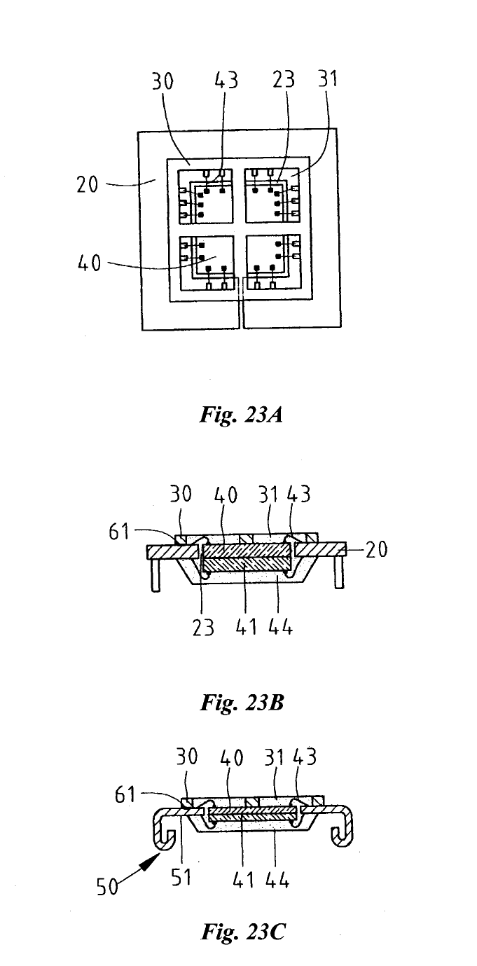

As indicated in FIG. 23A, FIG. 23B, and FIG. 23C, the drawings of the twenty-second embodiment of the invention herein which illustrate that the bridging element 30 is itself a heat sink having a plurality of spaces 31, the foundational element 20 space 23 is unsealed, the chip 40 is stacked with another chip 41, and the conduction pads 61 are conjoined to the bridging element 30 such that the bridging element 30 has a means of grounding or electromagnetic interference prevention. Furthermore, the embodiment shown in FIG. 23C and FIG. 23B is of an identical structural arrangement; however, in the structural arrangement of FIG. 23C, the foundational element 50 is a lead frame.

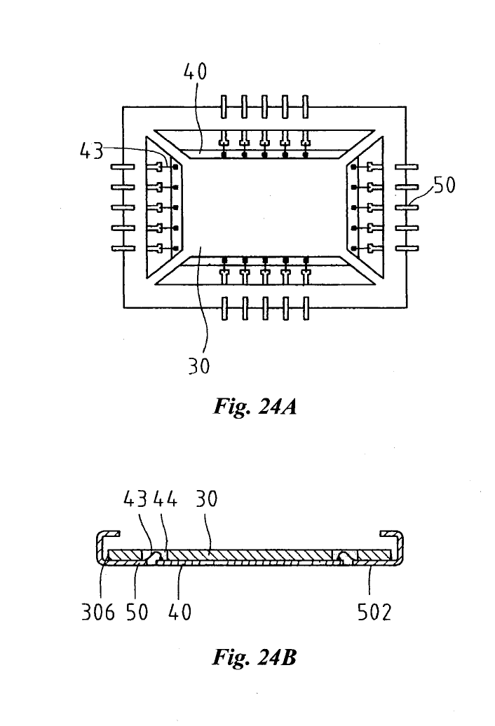

As indicated in FIG. 24A and FIG. 24B, the drawings of the twenty-third embodiment of the invention herein which illustrate that the chip 40 along with the foundational element 50 are conjoined to the bridging element 30 and, furthermore, the foundational element 50 has at least a portion that projects through the bridging element 30 lateral periphery 306 and is externally exposed, while its lower surface 502 is exposed at the exterior of the encapsulant resin 44 and thus, the said embodiment may be in a stacked structural arrangement with other semiconductor packages.

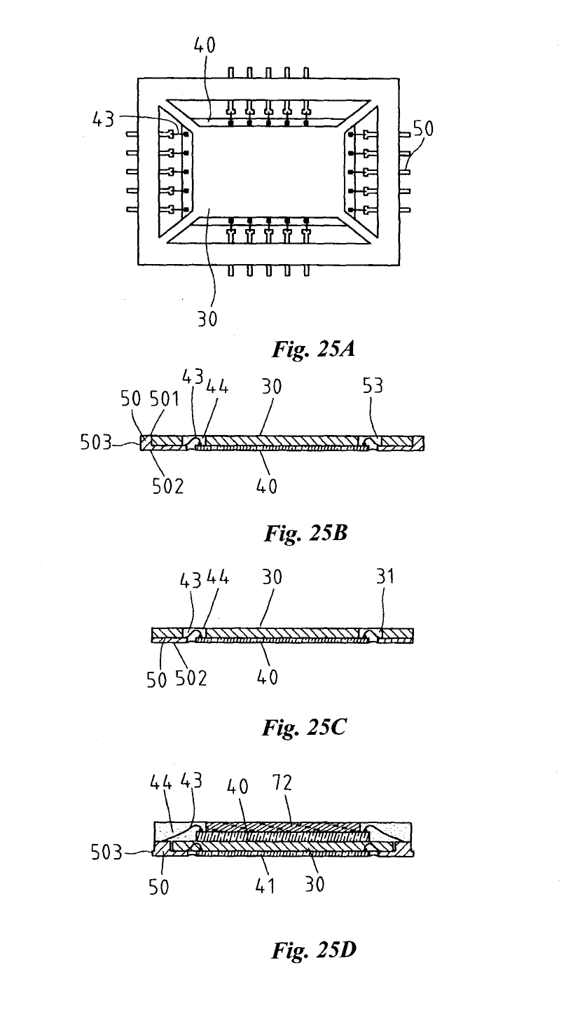

As indicated in FIG. 25A, FIG. 25B, FIG. 25C, and FIG. 24D, the drawings of the twenty-fourth embodiment of the present invention in which, as indicated in FIG. 25B, the chip 40 as well as the bridging element 30 are nested in a stepped space 53 of the foundational element 50 and since the stepped space 53 is cavitated in the foundational element 50, a plurality of upper surfaces are formed, wherein the said embodiment may be placed in external electrical connection via the upper surface 501, the lower surface 502 and (or) the lateral periphery 503 of the foundational element 50 and, furthermore, packaged with other semiconductor packages in a stacked structural arrangement; as indicated in FIG. 25C, wherein the foundational element 50 lower surface 502 is exposed at the exterior of the encapsulant resin 44 and, as shown in FIG. 25D, the chips 40 and 41 are conjoined to the bridging element 30 upper and lower surfaces, an optical element 72 is disposed on the chip 40 and, furthermore, the foundational element 50 lateral periphery 503 projects outside the encapsulant resin 44 and extends outwards.

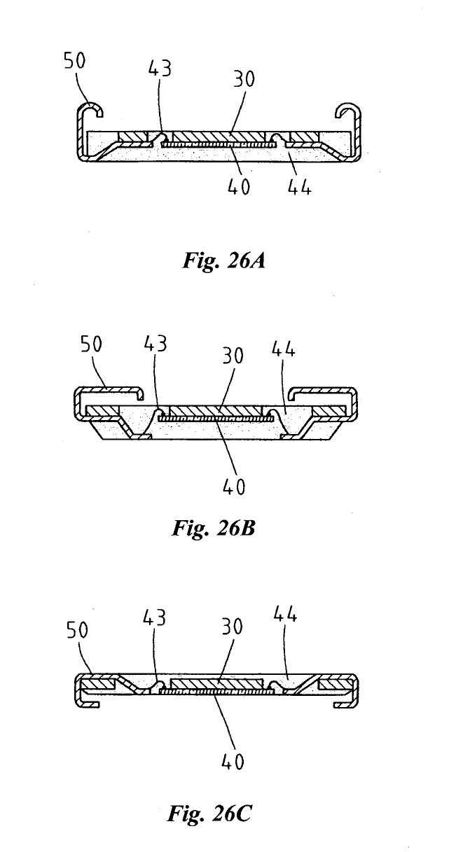

As indicated in FIG. 26A, FIG. 26B, and FIG. 26C the drawings of the twenty-fifth embodiment of the invention herein which illustrate that the active surface of the chip 40 along with the foundational element 50 are conjoined to the bridging element 30, the foundational element 50 has a plurality of upper surfaces as well as a plurality of lower surfaces and, furthermore, the embodiment shown in FIG. 26A, FIG. 26B, and FIG. 26C may be packaged with other semiconductor packages in a stacked structural arrangement.

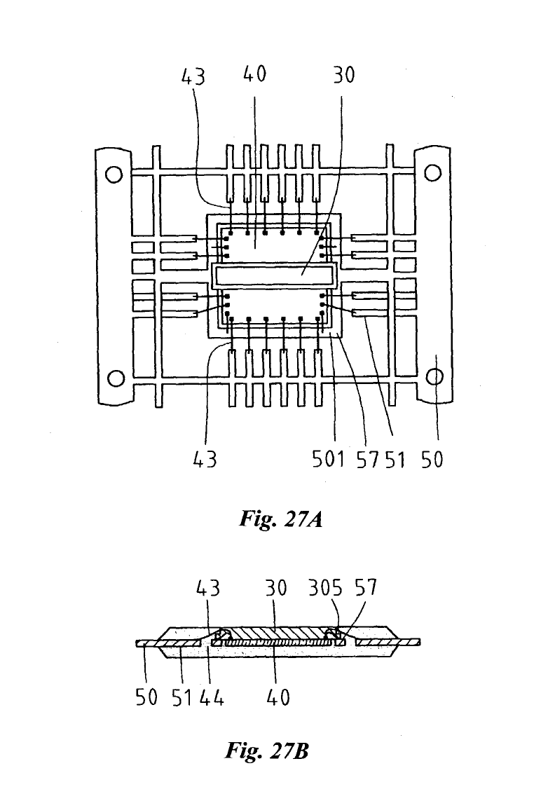

As indicated in FIG. 27A and FIG. 27B, the drawings of the twenty-sixth embodiment of the invention herein which illustrate that the foundational element 50 has a hollow frame 57 and a plurality of inner leads 51, wherein the hollow frame 57 of the foundational element 50 is situated around the chip 40 and served as a conductive ring, furthermore the hollow frame 57 upper surface 501 may be disposed with an insulator (not shown in the drawings) to prevent conductive elements 43 from contacting the hollow frame 57 due to collapse or sag and causing a short circuit; in the said embodiment, the bridging element 30 has a plurality of upper surfaces with a recessed portion 305 formed their peripheries and the inner leads 51 of the foundational element 50 are exposed at the exterior of the encapsulant resin 44 and are straight in contour.

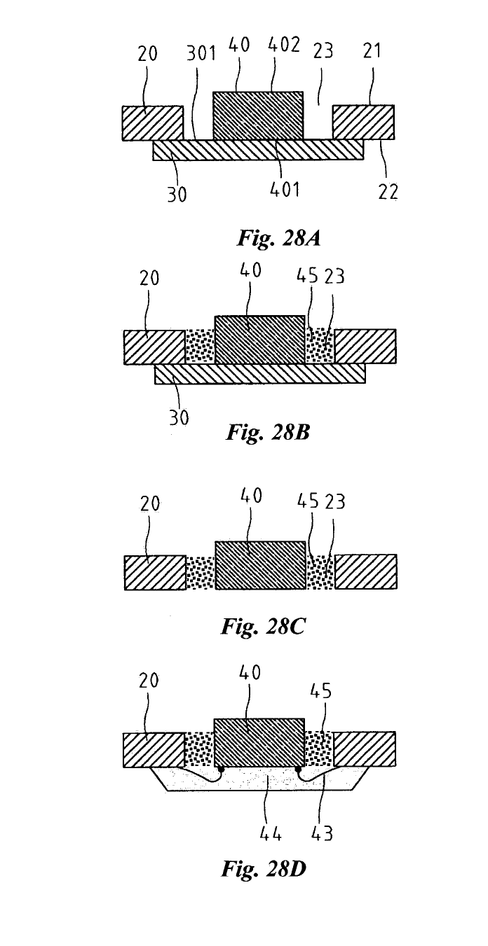

As indicated in FIG. 28A, FIG. 28B, FIG. 28C, and FIG. 28D, the fabrication process flow and semiconductor package drawings of the twenty-seventh embodiment of the present invention, wherein the bridging element 30 is of another structural arrangement, the arrangement consisting of the suspended semiconductor package herein with a substrate serving as the foundational element; as shown in FIG. 28A, the first surface (active surface) 401 of the chip 40 and the lower surface 22 of the foundational element 20 (or a plurality thereof) are conjoined to the upper surface 301 of the bridging element 30, wherein the foundational element 20 is situated around the chip 40 and, furthermore, the second surface 402 of the chip 40 projects (or does not project) as a planar superficies from the upper surface 21 of the foundational element 20; as shown in FIG. 28B, an appropriate volume of an adhesive means 45 is filled into the space 23 of the foundational element 20, the said adhesive means 45 fixing the chip 40 inside the foundational element 20 space 23; as shown in FIG. 28C, since the chip 30 has already been fixed and suspended within the space 23, the bridging element 30 is removed from the foundational element 20 (the bridging element 30 may also be left in place as required); as shown in FIG. 28D, the conductive elements 43 are electrically connected the foundational element 20 to the chip 40, then an encapsulant resin 44 encapsulates the chip 40, the foundational element 20, the adhesive means 45 and the conductive elements 43 to complete the suspended semiconductor package of the invention, wherein the adhesive means 45 and the encapsulant resin 44 are of an identical material. Moreover, the said embodiment accommodates the placement of a plurality of chips (not shown in the drawings) inside the space 23, the said plurality of chips (not shown in the drawings) arrayed such that the following suspended semiconductor package of the invention herein may be singulated apart vertically or horizontally to produce differently shaped semiconductor packages.

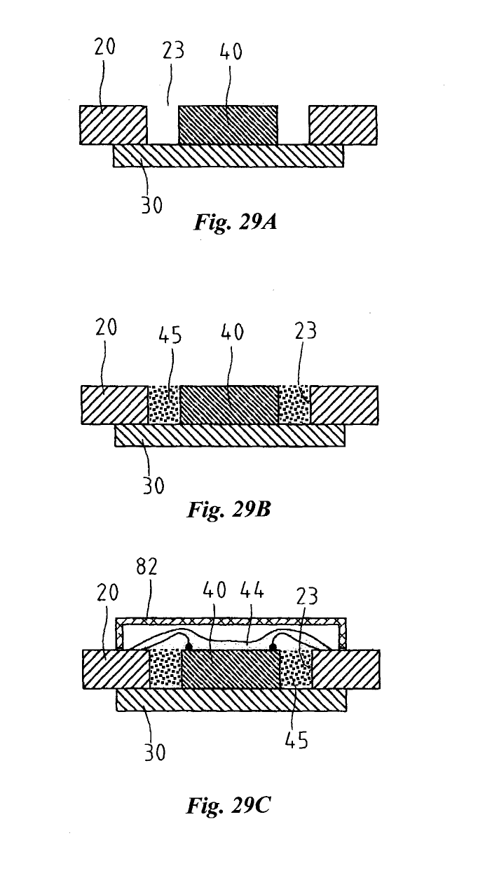

As indicated in FIG. 29A, FIG. 29B, and FIG. 29C, the fabrication process flow and semiconductor package drawings of the twenty-eighth embodiment of the present invention, the said FIG. 29A, FIG. 29B, and FIG. 29C consisting of an arrangement in which the suspended semiconductor package of the invention herein with a substrate serving as the foundational element; as shown in FIG. 29A, the inactive surface of the chip 40 and the foundational element 20 (or a plurality thereof) are conjoined to the bridging element 30; as shown in FIG. 29B, an appropriate volume of an adhesive means 45 is filled into the space 23 of the foundational element 20; and as shown in FIG. 29C, the chip 40 is then fixed and suspended within the space 23 and, furthermore, the lid 82 is also completed, wherein the lid 82 of the embodiment herein is an optical element and since the lid 82 overlays the conductive elements 43, the use of an encapsulant resin 44 is optional, moreover the bridging element 30 may be removed or allowed to remain as required, the bridging element 30 in the embodiment herein is not removed; the adhesive means 45 and the encapsulant resin 44 are of an identical material and, furthermore, during the fabrication process, the adhesive means 45 may be first filled into the foundational element 20 space 23 and the chip 40 thereafter placed inside the space 23 and, as such, the adhesive means 45 is capable of both fixing as and suspending the chip 40 within the space 23 of the foundational element 20.

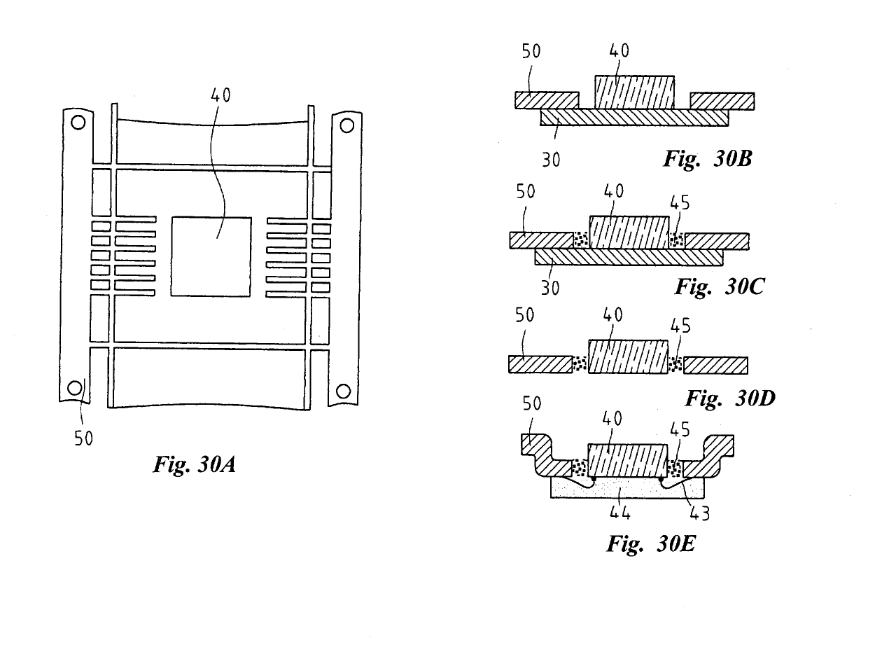

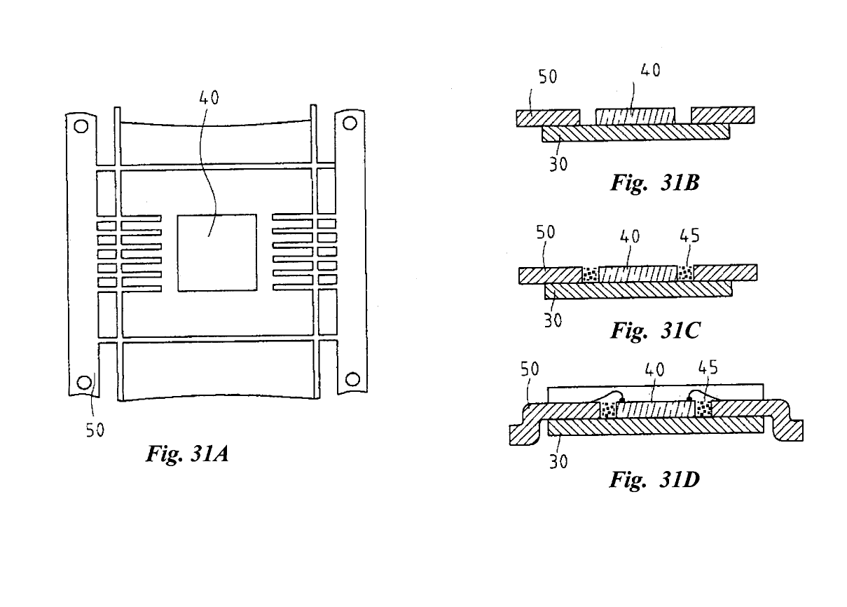

As previously elaborated (regarding the suspended semiconductor package of the present invention in FIG. 28A, FIG. 28B, FIG. 28C, and FIG. 28D as well as in FIG. 29A, FIG. 29B, and FIG. 29C), the invention herein may utilize a structure in which the foundational element 50 is a lead frame which, as shown in FIG. 30A, FIG. 30B, FIG. 30C, FIG. 30D, and FIG. 30E as well as FIG. 31A, FIG. 31B, FIG. 31C, and FIG. 31D, similarly achieves a thinner semiconductor package thickness and less material usage.

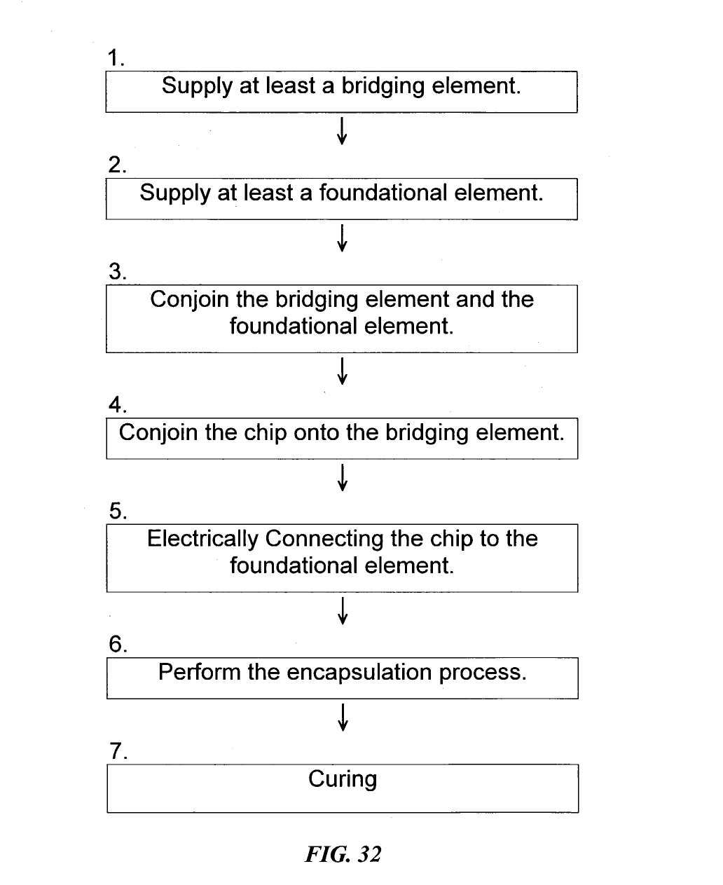

As indicated into FIG. 32, the fabrication process of the most preferred embodiment of invention herein is described below:

<Step 1>Supply at least a bridging element.

<Step 2>Supply at least a foundational element.

<Step 3>Conjoin the bridging element and the foundational element.

<Step 4>Conjoin the active surface of the chip onto the bridging element.

<Step 5>Electrically connecting the chip and the foundational element.

<Step 6>Perform encapsulation process.

<Step 7>Curing.

Of these procedures, Step 1 and Step 2 may be completed at the same time; the bridging element may be formed while the foundational element is made or vice-versa. As such, the Step 1 to Step 3 may be simultaneously accomplished; and the bridging element may be formed by a conductive material, an adhesive tape, a film, an optical element, a chip or any other type of materials.

In Step 2, the foundational element may be of different shapes as required; and the foundational element may be formed by a substrate (printed circuit board) or a lead frame, wherein the substrate may consist of resin, plastic, film, ceramic or any other type of materials.

Step 4 and Step 5 may also be complete simultaneously; as a flip chip is conjoined to the bridging element, the electrical connection of the conductive elements is completed following their conjoinment.

In Step 5, if the bridging element is a conductive part, then the conductive elements may electrically connect the chip to the bridging element, furthermore the conductive elements may also electrically connect the bridging element to the foundational element.

Between Step 4 and Step 5, the adhesive means may be poured in and after the chip adheres to the foundational element, a determination is made as to whether the bridging element is removed or not according to requirements.

Following the completion of Step 7, the semiconductor package may be singulated apart as requirement, furthermore if the foundational element is a lead frame, then the lead frame may be singulation.

Since other differing structural arrangements may be derived from each of the said embodiments, the invention herein has only been disclosed partially rather than entirely. As such, the disclosed structure of the present invention still substantiates that the suspended semiconductor package of the invention herein enables a semiconductor package possessing genuine manufacturing utility, including a thinner semiconductor package thickness, optimal heat dissipation, excellent electrical characteristics, and less fabrication material. However, the foregoing section only describes the most preferred embodiment of the invention herein and shall not be construed as a limitation of the claims of the present invention. Furthermore, all modifications and embellishments based on the patent application claims of the present invention shall remain proprietary to the scope and claims of the invention herein.

What is claimed is:

1. A suspended semiconductor package comprised of:
at least a bridging element having at least an upper surface and at least a lower surface;
at least a chip having a first surface and a second surface, wherein at least a surface is the active surface, with at least a portion of the said active surface conjoined to the said bridging element lower surface;
at least a foundational element having at least an upper surface and at least a lower surface, with at least a portion of the said foundational element being situated around the said chip; and
at least a conductive wire electrically connected the said chip and the said foundational element.

2. The suspended semiconductor package of claim 1, wherein the said bridging element does not contact the said foundational element.

3. The suspended semiconductor package of claim 1, wherein the said bridging element contacts the said foundational element.

4. The suspended semiconductor package of claim 1, wherein the said foundational element has at least a penetrable space capable of nesting the said chip.

5. The suspended semiconductor package of claim 1, wherein either surface of the said chip is coupled with at least an additional chip.

6. The suspended semiconductor package of claim 1, wherein the said bridging element has at least a penetrable space.

7. The suspended semiconductor package of claim 1, wherein the said bridging element is employed as a substrate.

8. The suspended semiconductor package of claim 1, wherein the said bridging element has at least a trace and at least a penetrable space capable of nesting the said chip, the said trace proceeding from the said bridging element upper surface through its said penetrable space and extending to its said lower surface.

9. The suspended semiconductor package of claim 1, wherein the said bridging element has exterior wall capability.

10. The suspended semiconductor package of claim 1 the said bridging element upper surface or the said foundational element accommodate the disposing of conductive balls.

11. The suspended semiconductor package of claim 1, wherein the said bridging element is employed as a chip.

12. The suspended semiconductor package of claim 1, wherein the said bridging element is employed as a heat sink.

13. The suspended semiconductor package of claim 1, wherein the said bridging element is employed as an optical element.

14. The suspended semiconductor package of claim 1, further comprises a lid, wherein the said lid is employed as an optical element.

15. The suspended semiconductor package of claim 1, wherein the said bridging element consists of at least a submember.

16. The suspended semiconductor package of claim 1, wherein the said second surface of the said chip projects from an encapsulant resin.

17. The suspended semiconductor package of claim 1, further comprises a component, and the said component consisting of an electrical component or an electronic component.

18. The suspended semiconductor package of claim 1, wherein either surface of the said chip is coupled with at least a heat sink.

19. The suspended semiconductor package of claim 1, wherein the said conductive wire is electrically connected the said chip to the said bridging element.

20. The suspended semiconductor package of claim 1, wherein the said foundational element is employed as a substrate.

21. The suspended semiconductor package of claim 4, wherein the said foundational element has at least a trace that proceeds from its upper surface through the said penetrable space and extends to its said lower surface.

22. The suspended semiconductor package of claim 1, wherein the said foundational element is employed as a lead frame, the said foundational element having at least a upper surface and at least a lower surface, wherein at least a portion of the said foundational element lower surface is exposed at the exterior of the said encapsulant resin.

23. The suspended semiconductor package of claim 3, wherein the said foundational element and the said bridging element are merged into a single unitary and, furthermore, there are at least two upper surfaces such that the conductive wire electrically connected the said chip to the said second upper surface.

24. A suspended semiconductor package comprised of:
at least a bridging element having at least an upper surface and at least a lower surface, the said lower surface having at least a trace;
at least a foundational element having at least an upper surface and at least a lower surface, with at least a portion of the said foundational element conjoined to the said bridging element lower surface;
at least a flip chip having a first surface and a second surface, wherein at least a surface is the active surface, the said active surface having at least a conductive element; and
at least a portion of the said active surface is conjoined to the said bridging element by the said conductive element.

25. The suspended semiconductor package of claim 24, wherein the said bridging element has at least a penetrable space.

26. The suspended semiconductor package of claim 24, wherein the said foundational element is employed as a lead frame.

27. The suspended semiconductor package of claim 24, wherein the said bridging element is employed as a chip.

28. The suspended semiconductor package of claim 24, wherein the said foundational element has at least a penetrable space capable of nesting the said chip.

29. The suspended semiconductor package of claim 24, wherein either surface of the said chip is coupled with at least an additional chip.

30. The suspended semiconductor package of claim 24, wherein either surface of the said chip is coupled with at least a heat sink.

31. The suspended semiconductor package of claim 24, further comprises a component, and the said component consisting of an electrical component or an electronic component.

32. The suspended semiconductor package of claim 24, wherein the said bridging element upper surface or the said foundational element accommodate the disposing of conductive balls.

33. A suspended semiconductor package comprised of:
at least a chip having a first surface and a second surface, wherein at least a surface is the active surface;
at least a foundational element having at least an upper surface and at least a lower surface, with at least a portion of the said foundational element situated around the said chip;
at least an adhesive means that adheres at least a portion of the said chip to at least a portion of the said foundational element; and
at least a conductive wire electrically connected the said chip to the said foundational element.

34. The suspended semiconductor package of claim 33, wherein the said foundational element is employed as a substrate.

35. The suspended semiconductor package of claim 33 the said foundational element is employed as a lead frame.

36. The suspended semiconductor package of claim 33 the said foundational element has at least a penetrable space and, furthermore, the said chip is nested inside the said penetrable space.

37. The suspended semiconductor package of claim 33, further comprises at least a component, and the said component consisting of an electrical component or an electronic component.

38. The suspended semiconductor package of claim 33, wherein either surface of the said chip is coupled with at least an additional chip.

39. The suspended semiconductor package of claim 33, wherein the said second surface of the said chip projects from an encapsulant resin.

40. The suspended semiconductor package of claim 33, further comprises at least a bridging element.

41. The suspended semiconductor package of claim 33, further comprises a lid, wherein the said lid is employed as an optical element.
